(19) United States
(12) Patent Application Publication
(10) Pub. No.: US 2022/0168865 A1
(43) Pub. Date: Jun. 2, 2022

(54) DOUBLE-SIDE POLISHING METHOD

(71) Applicant: SHIN-ETSU HANDOTAI CO., LTD., Tokyo (JP)

(72) Inventor: Yuki TANAKA, Nishigo-mura (JP)

(73) Assignee: SHIN-ETSU HANDOTAI CO., LTD., Tokyo (JP)

(21) Appl. No.: 17/600,548

(22) PCT Filed: Feb. 27, 2020
(86) PCT No.: PCT/JP2020/007893

§ 371 Date: Sep. 30, 2021

(30) Foreign Application Priority Data
Apr. 11, 2019 (JP) 2019-075625

(51) Int. Cl. B24B 37/08; B24B 37/28; B24B 37/04; B24B 7/22

(52) U.S. Cl. CPC B24B 37/08; B24B 7/228; B24B 37/042; B24B 37/28

(57) ABSTRACT

A double-side polishing method including: disposing a wafer between a polishing pad attached to an upper surface of a lower turn table and a polishing pad attached to a lower surface of an upper turn table provided above the lower turn table; and polishing both sides of the wafer. An absolute value of a difference between a gap at inner circumferential portions of the two polishing pads and a gap at outer circumferential portions thereof is defined as a pad gap. The pad gap is larger when the both sides of the wafer are polished than when the two polishing pads are dressed. This provides a double-side polishing method that simultaneously achieves enhancement of quality level (processing precision) and extension of cloth life.

### TECHNICAL FIELD

The present invention relates to a double-side polishing method.

### BACKGROUND ART

In a double-side polishing method for polishing both sides of a wafer which is disposed between a polishing pad attached to an upper surface of a lower turn table and a polishing pad attached to a lower surface of an upper turn table, the two polishing pads are kept in the constant shapes. This is one of important factors to achieve stable processing precision for wafer shapes. For this purpose, uneven wearing of polishing pads due to dressing, polishing, and so forth has been conventionally suppressed through operations under such conditions that upper and lower turntables are formed of a low-thermal-expansion material and the upper and lower turntables are kept parallel to each other (see Patent Documents 1, 2).

Nevertheless, polishing pads (cloths) pasted on upper and lower turntables are unevenly worn and deformed due to dressing and polishing, while being influenced by the structural precision of the turntables. Hence, from such a longitudinal perspective of continuing polishing in batches over and over, the operations have been carried on while the upper and lower turntables are kept parallel to thereby suppress uneven wearing due to dressing, so that the wafer processing precision has been maintained for a long period.

However, even though setting the turntables or pads parallel to each other improves the precision and stability of the shapes, it has been difficult to attain high quality level in that the polishing-slurry drainage is inhibited.

### CITATION LIST

### Patent Literature

Patent Document 1: JP 2001-79756 A

Patent Document 2: JP 2008-44098 A

### SUMMARY OF INVENTION

### Technical Problem

The present invention has been made to solve the above problems. An object of the present invention is to propose a double-side polishing method that overcomes a trade-off between enhancement of wafer-quality level (processing precision) and extension of cloth life so as to achieve the two simultaneously.

### Solution to Problem

To achieve the object, the present invention provides a double-side polishing method comprising:

disposing a wafer between a polishing pad attached to an upper surface of a lower turn table and a polishing pad attached to a lower surface of an upper turn table provided above the lower turn table; and

polishing both sides of the wafer, wherein

an absolute value of a difference between a gap at inner circumferential portions of the two polishing pads and a gap at outer circumferential portions thereof is defined as a pad gap, and

the pad gap is larger when the both sides of the wafer are polished than when the two polishing pads are dressed.

According to such a double-side polishing method, when both sides of a wafer are being polished, the pad gap is large, that is, the degree of inclination between the two polishing pads is high. Thereby, slurry is supplied and discharged efficiently, and the wafer-quality level (processing precision) is successfully enhanced. Moreover, when the two polishing pads are being dressed, the pad gap is small, that is, the degree of inclination between the two polishing pads is low. Thereby, wearing of the polishing pads during the dressing is suppressed, and the cloth life is successfully extended.

Thus, it is possible to simultaneously achieve enhancement of wafer-quality level (processing precision) and extension of cloth life.

Preferably, the pad gap is larger during the polishing than during the dressing by a value of 20 μm or more and 100 μm or less.

In this manner, when the difference between the pad gap during the polishing and the pad gap during the dressing is set 20 μm or more, slurry is efficiently supplied and discharged during the polishing; in addition, wearing of the polishing pads is suppressed during the dressing. Thus, the cloth life enabling predetermined GBIR (Global Backside Ideal Range) can be extended. Meanwhile, when the difference between the pad gap during the polishing and the pad gap during the dressing is set 100 μm or less, the wafer will be free from a risk of coming off from a carrier during the polishing.

In this case, preferably, the two polishing pads are set parallel to each other during the dressing, and the two polishing pads are set non-parallel to each other during the polishing.

The pad gap during the dressing is set at 0 μm (parallel). In such manner as described above, the control of the pad gap is simple. Specifically, in the dressing event, the two polishing pads can be made parallel by setting the lower turn table parallel to the upper turn table, for example. Meanwhile, in the polishing event, the two polishing pads can be made non-parallel by tilting the upper turn table to set the lower turn table non-parallel to the upper turn table, for example.

In the present invention, the lower turn table and the upper turn table are preferably made of a low-thermal-expansion material having a linear thermal expansion coefficient of 6×10⁻⁶/K or less. The lower limit value thereof is not particularly limited and can be 0.1×10⁻⁶/K or more.

When the lower turn table and the upper turn table are formed of such a low-thermal-expansion material, this makes thermal deformation of these turntables difficult despite friction heat between the wafer and the polishing pads, and accordingly can eliminate risks of deforming the shapes of the polishing pads due to the thermal deformation, which would otherwise adversely influence the wafer-quality level (processing precision) and cloth life.

More preferably, the pad gap is adjusted by changing an inclination of the upper turn table.

When the pad gap between the two polishing pads is controlled by immobilizing the lower turn table and changing the inclination of the upper turn table as described above, this means that only the motion of the upper turn table is controlled. Thus, the pad gap can be easily controlled.

### Advantageous Effects of Invention

As described above, according to the present invention, the pad gap is larger when both sides of a wafer are polished than when two polishing pads are dressed. This makes it possible to eliminate a trade-off between enhancement of wafer-quality level (processing precision) and extension of cloth life, and achieve these simultaneously. For example, the lower turn table is set non-parallel to the upper turn table during the polishing, so that the wafer-quality level (processing precision) is successfully enhanced. In addition, setting the lower turn table parallel to the upper turn table during the dressing can suppress uneven wearing of the pads and extend the cloth life while enabling favorable wafer shapes even when the number of dressings is increased (more abrasion by dressings).

### BRIEF DESCRIPTION OF DRAWINGS

FIG. 1 is a flowchart for illustrating a double-side polishing method according to the present invention.

FIG. 2 is an illustration showing relations of two polishing pads during polishing and during dressing.

FIG. 3 is an illustration showing a relation of two polishing pads without uneven wearing during the dressing.

FIG. 4 is an illustration showing a relation of the two polishing pads without uneven wearing during the polishing.

FIG. 5 is an illustration showing a relation of two polishing pads with uneven wearing during the polishing.

FIG. 6 is an illustration showing a relation of the two polishing pads with uneven wearing during the dressing.

FIG. 7 is an illustration showing an example of a double-side polishing apparatus with which the inventive double-side polishing method can be carried out.

FIG. 8 is a graph showing a relation between the number of dressings and wafer quality (GBIR).

### DESCRIPTION OF EMBODIMENTS

As noted above, before both sides of a wafer are polished, the outermost layers of polishing pads are removed, for example, by sliding a dresser having diamond abrasive grains thereon so as to refresh the surfaces of the polishing pads having been degraded by such polishing. Such removal of the outermost layers of polishing pads to refresh the surfaces of the polishing pads is called dressing. Nevertheless, when the number of the dressing operations is increased, the shapes of the polishing pads are gradually changed and fail to meet the shape requirement based on wafer flatness early. Consequently, a problem arises that the cloth life enabling predetermined quality, for example, GBIR, is shortened.

Accordingly, the present inventor has earnestly studied the above problems and consequently found that such wearing of polishing pads as to shorten the cloth life is dominantly influenced during the dressing event rather than during the polishing event. To put it differently, the present inventor has found that enhancement of the quality of wafer to be polished and extension of cloth life can be simultaneously accomplished by: increasing the absolute value of a difference between a gap at inner circumferential portions of the two polishing pads and a gap at outer circumferential portions thereof (pad gap) during the polishing event of polishing both sides of the wafer to efficiently supply and discharge slurry; and decreasing the absolute value of the pad gap during the dressing event of dressing the two polishing pads to suppress the wearing of the two polishing pads. These findings have led to the completion of the present invention.

Specifically, the present invention is a double-side polishing method comprising:

disposing a wafer between a polishing pad attached to an upper surface of a lower turn table and a polishing pad attached to a lower surface of an upper turn table provided above the lower turn table; and

polishing both sides of the wafer, wherein

an absolute value of a difference between a gap at inner circumferential portions of the two polishing pads and a gap at outer circumferential portions thereof is defined as a pad gap, and

the pad gap is larger when the both sides of the wafer are polished than when the two polishing pads are dressed.

Hereinafter, embodiments of the present invention will be specifically described based on the accompanying drawings, but the present invention is not limited thereto.

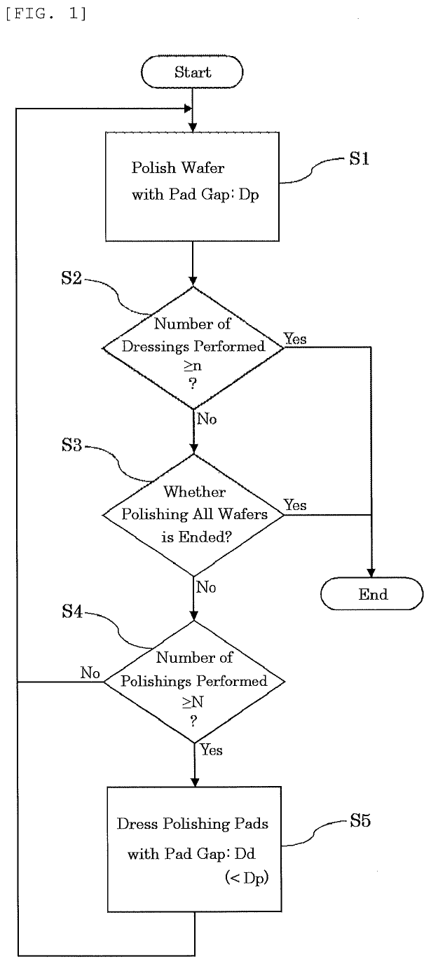

FIG. 1 illustrates the inventive double-side polishing method.

The double-side polishing method to be described below can be carried out, for example, with a 4-way double-side polishing apparatus having driving units of a lower turn table, an upper turn table, a sun gear, and an internal gear. Additionally, in order to adjust the degree of inclination between two polishing pads, the polishing apparatus preferably has a movable upper turn table, that is, the inclination of the upper turn table is adjustable. Nevertheless, the process of adjusting the degree of inclination between the two polishing pads is not particularly limited.

First, as shown in Step S1, a wafer(s) are disposed between a polishing pad attached to an upper surface of a lower turn table and a polishing pad attached to a lower surface of an upper turn table provided above lower turn table to then polish the wafer(s) under a condition of a pad gap Dp. Here, the number of wafers that can be polished by single polishing is, for example, 5 (one batch).

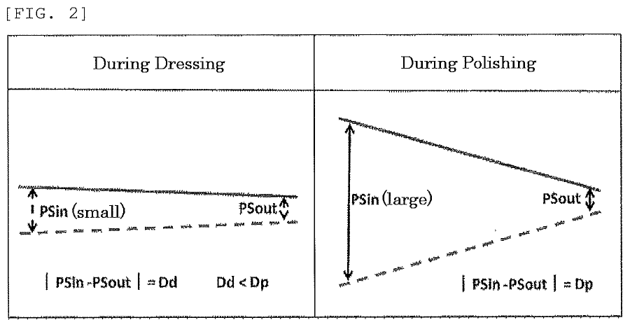

In this event, as shown under “During Polishing” in FIG. 2, the pad gap Dp, which is an absolute value of a difference between a gap PSin at inner circumferential portions of the two polishing pads and a gap PSout at outer circumferential portions thereof, has such a sufficiently large value (for example, 60 μm) that slurry is supplied and discharged efficiently. Additionally, the pad gap Dp is easily controlled by changing the gap PSin between the inner circumferential portions of the respective two polishing pads relative to the gap PSout between the outer circumferential portions of the respective two polishing pads, that is, by increasing PSin.

Next, as shown in Step S2, whether or not the number of dressings performed is “n” times or more is checked. Here, “n” is a numerical value indicating the number of dressings that consequently enable wafers to have predetermined quality (GBIR). As described later, this numerical value can be increased in the present invention.

Then, if the number of dressings is “n” times or more, the operator is notified that the polishing pads need to be replaced, for example. After that, this flow is ended. Meanwhile, if the number of dressings is not “n” times or more, the flow proceeds to Step S3.

Next, as shown in Step S3, whether or not polishing all the wafers is ended is checked. If polishing all the wafers has been ended, this flow is ended.

Meanwhile, if polishing all the wafers has not been ended, the flow proceeds to Step S4, and whether or not the number of polishings performed is N times or more is checked. Here, “N” is a numerical value indicating the frequency of dressings. N=1 means that polishing and dressing are alternately performed. N=5 means that single dressing is performed every five times of polishings performed (every 5 batches).

Then, if the number of polishings performed is not N times or more, the flow returns to Step S1, and the wafer polishing is performed again with the pad gap being set to Dp.

Meanwhile, if the number of polishings performed is N times or more, the flow proceeds to Step S5, and the two polishing pads are dressed under a condition of a pad gap Dd.

Here, the pad gap Dd during the dressing has a smaller value than the pad gap Dp during the polishing. This is because when the pad gap Dd during the dressing has a small value, more preferably when the pad gap Dd is 0 μm (the two polishing pads are parallel), deformation of the polishing pads during the dressing is suppressed, so that the dressing life during which wafers having predetermined quality can be obtained is successfully extended (the numerical value of “n” in Step S2 can be increased).

Note that the pad gap Dd is easily controlled by changing the gap PSin between the inner circumferential portions of the respective two polishing pads relative to the gap PSout between the outer circumferential portions of the respective two polishing pads, that is, by decreasing PSin, as shown under “During Dressing” in FIG. 2.

Moreover, regarding the pad gaps Dp and Dd during the polishing and dressing, the pad gap Dp is preferably larger than the pad gap Dd by a value of 20 μm or more and 100 μm or less. Accordingly, during the polishing, slurry is efficiently supplied and discharged, and the wafers can avoid a risk of coming off from a carrier. Moreover, during the dressing, the wearing of the polishing pads is suppressed, so that the cloth life can be extended.

Next, after the dressing process in Step S5 is ended, the flow returns to Step S1, and the wafer polishing is performed again with the pad gap set to Dp.

Such novel polishing methodology of changing the pad gap between the polishing and dressing events according to the double-side polishing method as described above makes it possible to simultaneously accomplish the enhancement of wafer-quality level (processing precision) in the polishing and the extension of the cloth life by suppressing the wearing of polishing pads in the dressing.

Note that, regarding the terms inner circumferential portion and outer circumferential portion in the double-side polishing method, the inner circumferential portion refers to a circumferential portion close to a rotation shaft around which the two polishing pads in a ring shape are formed; and the outer circumferential portion refers to a circumferential portion located outwardly away from the inner circumferential portion. To put it differently, the locations of the inner circumferential portions and the outer circumferential portions are not particularly limited. There would be no problem, as long as their positional relations remain unchanged during the polishing and during the dressing.

Nevertheless, to readily detect the gap PSin at the inner circumferential portions and the gap PSout at the outer circumferential portions, the inner circumferential portions and the outer circumferential portions are preferably located at the respective innermost and outermost peripheries of the two annular polishing pads.

Hereinbelow, examples of pad shapes during the polishing and during the dressing will be described.

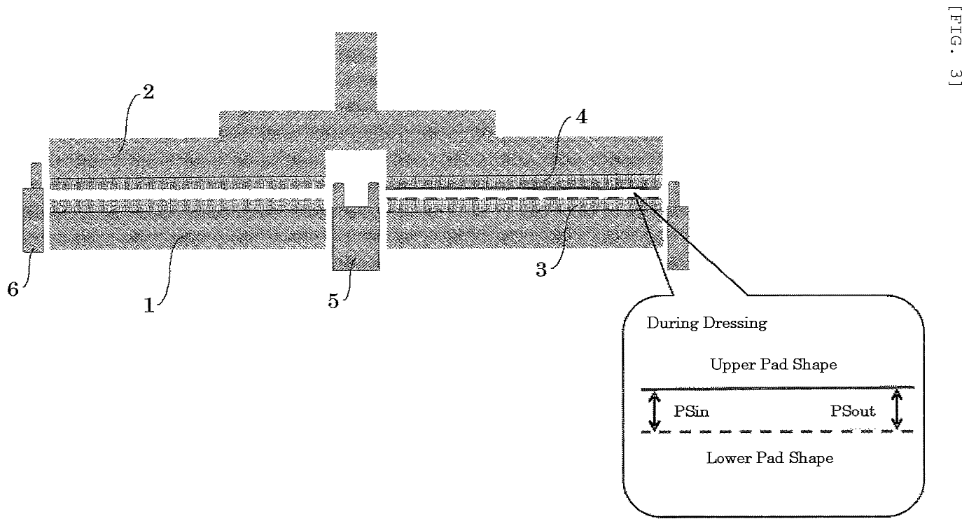

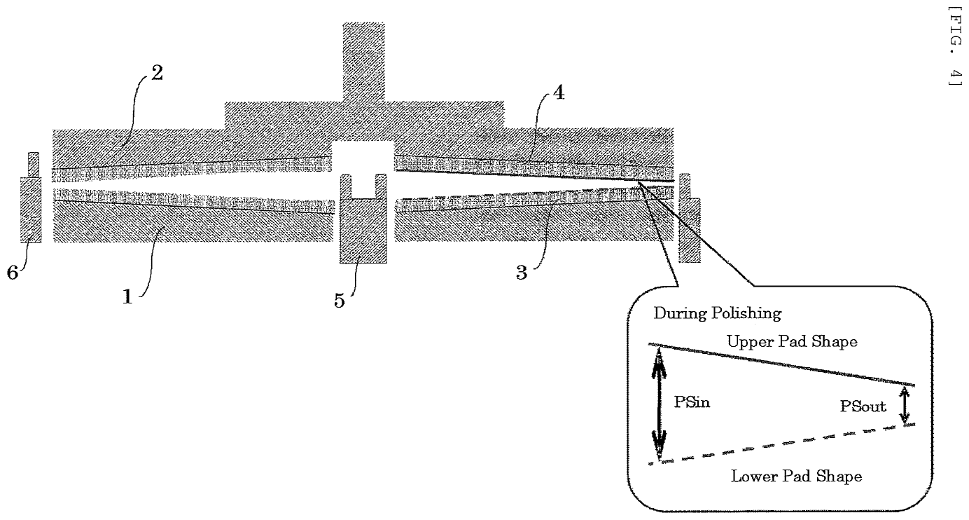

FIG. 3 shows a relation of two polishing pads without uneven wearing during the dressing. FIG. 4 shows a relation of the two polishing pads without uneven wearing during the polishing.

For example, as shown in FIG. 3, when an upper surface of a lower turn table 1 is parallel to a lower surface of an upper turn table 2 and two polishing pads 3, 4 are parallel to each other, such as immediately after the polishing pads 3, 4 are replaced, the difference between the gap PSin at the inner circumferential portions and the gap PSout at the outer circumferential portions is zero. Thus, in the dressing event, the upper surface of the lower turn table 1 is set parallel to the lower surface of the upper turn table 2, so that the two polishing pads 3, 4 are set parallel to each other. In this state where the pad gap Dd is zero, the polishing pads 3, 4 are dressed.

Moreover, from the state as shown in FIG. 3 where the upper surface of the lower turn table 1 is parallel to the lower surface of the upper turn table 2 and the two polishing pads 3, 4 are parallel to each other, the shape of the lower turn table 1 (lower-turn-table shape) and the shape of the upper turn table 2 (upper-turn-table shape) are altered as shown in FIG. 4 in the polishing event. Specifically, the upper surface of the lower turn table 1 is set non-parallel to the lower surface of the upper turn table 2, so that the two polishing pads 3, 4 are set non-parallel to each other. In this state where the pad gap Dp has a plus value (for example, 60 μm), the wafer(s) are polished.

Note that, in the polishing, at least one of the lower-turn-table shape and the upper-turn-table shape may be altered to set the two polishing pads 3, 4 non-parallel to each other.

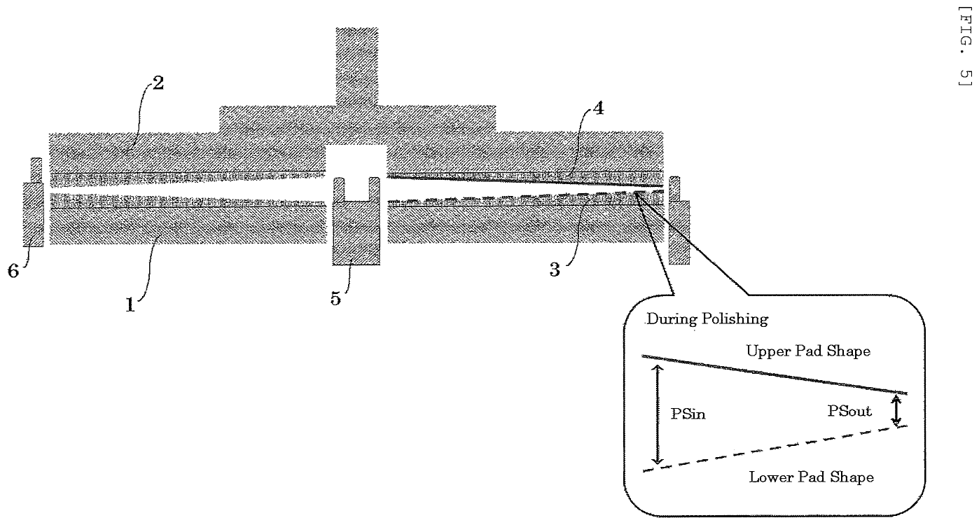

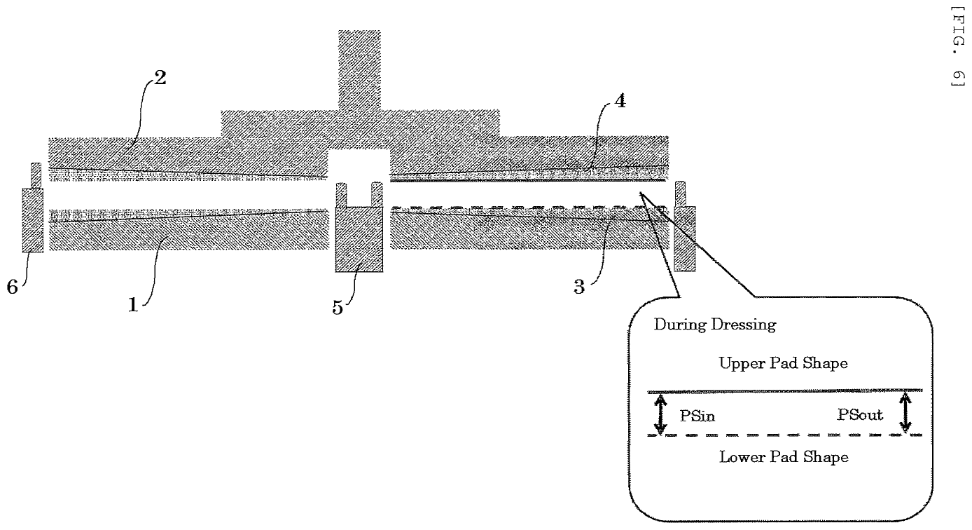

FIG. 5 shows a relation of two polishing pads with uneven wearing during the polishing. FIG. 6 shows a relation of the two polishing pads with uneven wearing during the dressing.

For example, when uneven wearing of the polishing pads 3, 4 continues, the two polishing pads 3, 4 become non-parallel to each other while the upper surface of the lower turn table 1 is parallel to the lower surface of the upper turn table 2 as shown in FIG. 5. In this state, the difference between the gap PSin at the inner circumferential portions and the gap PSout at the outer circumferential portions has a plus value. In this case, the upper surface of the lower turn table 1 is set parallel to the lower surface of the upper turn table 2 in the polishing event (the two may be unparallel to adjust the pad gap Dd), so that the two polishing pads 3, 4 are set non-parallel to each other. In this state where the pad gap Dp has a plus value (for example, 60 μm), the wafer(s) are polished.

Moreover, from the state as shown in FIG. 5 where the upper surface of the lower turn table 1 is parallel to the lower surface of the upper turn table 2 but the two polishing pads 3, 4 are non-parallel to each other, the shape of the lower turn table 1 (lower-turn-table shape) and the shape of the upper turn table 2 (upper-turn-table shape) are altered as shown in FIG. 6 in the dressing event. Specifically, the upper surface of the lower turn table 1 is set non-parallel to the lower surface of the upper turn table 2, so that the two polishing pads 3, 4 are set parallel to each other. In this state where the pad gap Dd is zero, the polishing pads 3, 4 are dressed.

Note that, in the dressing, at least one of the lower-turn-table shape and the upper-turn-table shape may be altered to set the two polishing pads 3, 4 parallel to each other.

The polishing methodology in which operations run under such conditions that the pad gap is changed between the polishing and the dressing events according to the above-described double-side polishing method makes it possible to provide a double-side polishing method that eliminates a trade-off between the enhancement of wafer-quality level (processing precision) and the extension of the cloth life so as to simultaneously achieve these.

### EXAMPLE

Hereinafter, the present invention will be described in detail with reference to Example of the present invention. However, the present invention is not limited thereto.

### Example

The following double-side polishing apparatus was used to verify the cloth life (the service life of polishing pads) during which predetermined GBIR was attained. Herein, GBIR is one of indicators for wafer flatness, and is a difference between the maximum and minimum values of distances from a reference plane on the back surface to the front surface of a wafer.

Details of Double-Side Polishing Apparatus

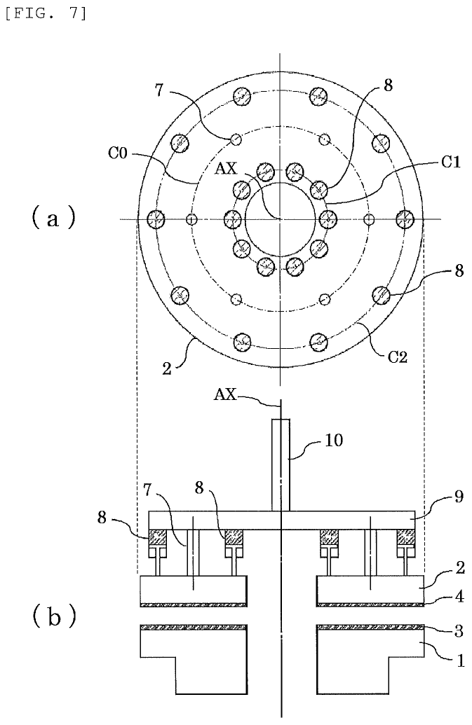

FIG. 7 shows an example of the double-side polishing apparatus with which the inventive double-side polishing method can be carried out.

Such a double-side polishing apparatus was used to conduct the following Example. Specifically, DSP-20B manufactured by Fujikoshi Machinery Corp. was used.

The double-side polishing apparatus was a 4-way type with a 20B size and had driving units of a lower turn table 1, an upper turn table 2, a sun gear 5, and an internal gear 6. The upper turn table 2 was linked to a suspension top plate 9 through six suspended columns 7 arranged on a concentric circle C0. The material of each suspended column 7 was SUS (stainless steel material). The material of the lower turn table 1 and the upper turn table 2 was Invar having small thermal expansion coefficient at around normal temperature (the thermal expansion coefficient=1.5×10⁻⁶/K to 4.0×10⁻⁶/K). The upper turn table 2 and the suspension top plate 9 were rotatable around a rotation shaft 10 having the same center as a central axis AX.

Ten actuators 8 were arranged on a concentric circle C1 having a smaller PCD (pitch circle diameter) by 300 mm than that of the concentric circle C0 on which the six suspended columns 7 were arranged. Specifically, the concentric circle C1 was located 150 mm inwardly apart from the concentric circle C0 on which the six suspended columns 7 were arranged. Further, ten actuators 8 were arranged on a concentric circle C2 having a larger PCD by 300 mm than that of the concentric circle C0 on which the six suspended columns 7 were arranged. Specifically, the concentric circle C2 was located 150 mm outwardly apart from the concentric circle C0 on which the six suspended columns 7 were arranged.

Each actuator 8 was an air cylinder utilizing compressed air as a driving source. When the tilt of the upper turn table 2 was adjusted, compressed air was supplied from a supply source outside the double-side polishing apparatus to the actuators 8 inside the double-side polishing apparatus to activate the actuators 8.

Further, when wafers were polished and polishing pads were dressed, the upper-turn-table shape, i.e., the inclination of the upper turn table, was altered, while the lower-turn-table shape was immobilized. Hence, the pad gap Dp during the polishing of both sides of wafers was adjusted to be larger than the pad gap Dd during the dressing of the two polishing pads 3, 4.

Experimental Conditions

As the wafers, P-type silicon single crystal wafers each having a diameter of 300 mm were used.

As the polishing pads, foamed polyurethane pads having a Shore A hardness of 85 were used.

As carriers, FRP was used in which glass fibers as insert on a titanium substrate was impregnated with epoxy resin. Fives carrier constituting one set were set in the double-side polishing apparatus, and one wafer was set in each carrier.

As slurry, a KOH-based slurry was used which contained silica abrasive grains and had an average particle size of 35 nm, abrasive-grain concentration of 1.0 wt %, and pH of 10.5.

The processing load was set at 180 gf/cm².

The processing time was set such that each carrier set had the optimum gap.

The rotation speed of each driving unit was set as follows: the upper turn table was −13.4 rpm, the lower turn table was 35 rpm, the sun gear was 25 rpm, and the internal gear was 7 rpm.

The polishing pads were dressed by bringing a dress plate having diamond abrasive grains electrodeposited thereon into sliding contact with each of the upper and lower polishing pads at 120 gf/cm² while pure water flowed. The sliding time was 1 hour.

The polishing and the dressing were alternately performed.

The processed wafers were subjected to SC-1 cleaning under a condition of (NH₄OH:H₂O₂:H₂O=1:1:15).

The pad gaps were calculated based on the measured radius profiles of the upper and lower pads. Moreover, how GBIR was changed relative to a reference value in accordance with the number of dressings was verified. Here, the reference value is GBIR with which a wafer is considered to have favorable shape, that is, the GBIR is smaller than the product standard value.

The verification was conducted under such conditions that the pad gap was set at 0 μm (the two polishing pads were parallel) during the dressing, while the pad gap was changed to 10 μm, 20 μm, 40 μm, and 60 μm during the polishing.

GBIR Calculation

Under the above experimental conditions, the wafer polishing and the dressing were alternately performed. After the cleaning, the flatness of the wafers was measured, and the GBIR was calculated. Note that the flatness of each cleaned wafer was measured using WaferSight manufactured by KLA Tencor. The GBIR was calculated, except for 2-mm regions around the edge of the wafer.

### Comparative Example

Details of Double-Side Polishing Apparatus

The same double-side polishing apparatus in Example described above was used.

Experimental Conditions

The same conditions as the experimental conditions of Example described above were set.

Nevertheless, the difference in the pad gap between the polishing and dressing events was set 0 μm. Specifically, the pad gaps in both of the polishing and dressing events were 40 μm.

GBIR Calculation

The GBIR was calculated by the same calculation method as in Example described above.

### (Verification Result)

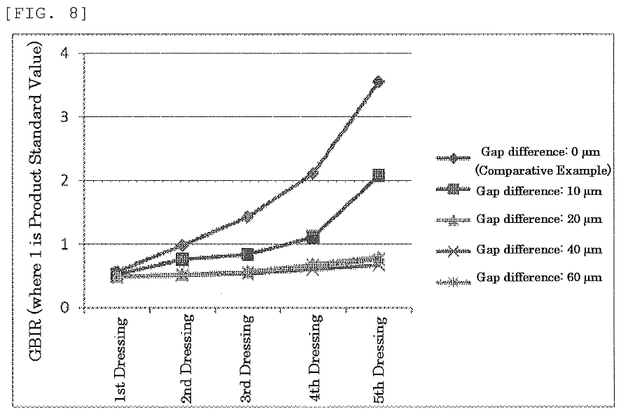

FIG. 8 shows a relation between the number of dressings and wafer quality (GBIR).

In this figure, the horizontal axis represents the number of dressings, and the vertical axis represents the GBIR. Note that each plot of both Example and Comparative Example represents an average value of five wafers in one batch.

Here, regarding the GBIR in the vertical axis, 1 indicates the product standard value. More specifically, in the figure, in the range where the GBIR is smaller than 1, the wafer-quality level (processing precision) is favorable. In other words, this means that wafers are successfully polished by using the polishing pads having been dressed just before the GBIR would exceed 1.

As apparent from the figure, with the gap difference of 0 μm (Comparative Example), when the wafers were polished after the dressing was performed three times, favorable wafer shapes were not obtained (GBIR exceeded 1). In contrast, with the gap difference of 10 μm, even when the wafers were polished after the dressing was performed three times, favorable wafer shapes were obtained. Further, it can be seen that with the gap differences of 20 μm, 40 μm, and 60 μm, when the wafers were polished even after the dressing was performed five times, the GBIR of the wafers resulting from the polishing did not exceed 1.

From the foregoing, it was demonstrated that the dressing life enabling favorable wafer shapes is successfully extended by at least setting the pad gap during the polishing different from the pad gap during the dressing, that is, by setting the two polishing pads non-parallel to each other during the polishing, and setting the two polishing pads parallel to each other or setting an equivalent state during the dressing.

Particularly, it was found out that when the pad gap during the polishing differs from the pad gap during the dressing by 20 μm or more, favorable wafer shapes are obtained even after the dressing is performed five times. This case demonstrated that dramatic extension of dressing life is possible.

As has been described hereinabove, the present invention makes it possible to provide a double-side polishing method which eliminates a trade-off between enhancement of wafer-quality level (processing precision) and extension of cloth life, and achieves these simultaneously.

It should be noted that the present invention is not limited to the above-described embodiments. The embodiments are just examples, and any examples that substantially have the same feature and demonstrate the same functions and effects as those in the technical concept disclosed in claims of the present invention are included in the technical scope of the present invention.

1-5. (canceled)

6. A double-side polishing method comprising:
disposing a wafer between a polishing pad attached to an upper surface of a lower turn table and a polishing pad attached to a lower surface of an upper turn table provided above the lower turn table; and
polishing both sides of the wafer, wherein
an absolute value of a difference between a gap at inner circumferential portions of the two polishing pads and a gap at outer circumferential portions thereof is defined as a pad gap, and
the pad gap is larger when the both sides of the wafer are polished than when the two polishing pads are dressed.

7. The double-side polishing method according to claim 6, wherein the pad gap is larger during the polishing than during the dressing by a value of 20 μm or more and 100 μm or less.

8. The double-side polishing method according to claim 6, wherein
the two polishing pads are set parallel to each other during the dressing, and
the two polishing pads are set non-parallel to each other during the polishing.

9. The double-side polishing method according to claim 7, wherein
the two polishing pads are set parallel to each other during the dressing, and
the two polishing pads are set non-parallel to each other during the polishing.

10. The double-side polishing method according to claim 6, wherein the lower turn table and the upper turn table are made of a low-thermal-expansion material having a linear thermal expansion coefficient of 6×10⁻⁶/K or less.

11. The double-side polishing method according to claim 7, wherein the lower turn table and the upper turn table are made of a low-thermal-expansion material having a linear thermal expansion coefficient of 6×10⁻⁶/K or less.

12. The double-side polishing method according to claim 8, wherein the lower turn table and the upper turn table are made of a low-thermal-expansion material having a linear thermal expansion coefficient of 6×10⁻⁶/K or less.

13. The double-side polishing method according to claim 9, wherein the lower turn table and the upper turn table are made of a low-thermal-expansion material having a linear thermal expansion coefficient of 6×10⁻⁶/K or less.

14. The double-side polishing method according to claim 6, wherein the pad gap is adjusted by changing an inclination of the upper turn table.

15. The double-side polishing method according to claim 7, wherein the pad gap is adjusted by changing an inclination of the upper turn table.

16. The double-side polishing method according to claim 8, wherein the pad gap is adjusted by changing an inclination of the upper turn table.

17. The double-side polishing method according to claim 9, wherein the pad gap is adjusted by changing an inclination of the upper turn table.

18. The double-side polishing method according to claim 10, wherein the pad gap is adjusted by changing an inclination of the upper turn table.

19. The double-side polishing method according to claim 11, wherein the pad gap is adjusted by changing an inclination of the upper turn table.

20. The double-side polishing method according to claim 12, wherein the pad gap is adjusted by changing an inclination of the upper turn table.

21. The double-side polishing method according to claim 13, wherein the pad gap is adjusted by changing an inclination of the upper turn table.
